(19) United States
(12) Patent Application Publication
(10) Pub. No.: US 2008/0304531 A1
(43) Pub. Date: Dec. 11, 2008

(54) Integrated broadband quantum cascade laser

(75) Inventors: Kamjou Mansour, LaCanada, CA (US); Alexander Soibel, S. Pasadena, CA (US)

Correspondence Address: SETH Z. KALSON;c/o INTOLLEVATE, P.O. BOX 52050, MINNEAPOLIS, MN, 55402, US

(73) Assignee: California Institute of Technology, Pasadena, CA (US)

(21) Appl. No.: 12/070,504

(22) Filed: Feb. 19, 2008

Related U.S. Application Data
(60) Provisional application No. 60/902,302, filed on Feb. 20, 2007.

(51) Int. Cl. H01S 5/026

(52) U.S. Cl. 372/50.121; 372/50.12

(57) ABSTRACT

A broadband, integrated quantum cascade laser is disclosed, comprising ridge waveguide quantum cascade lasers formed by applying standard semiconductor process techniques to a monolithic structure of alternating layers of claddings and active region layers. The resulting ridge waveguide quantum cascade lasers may be individually controlled by independent voltage potentials, resulting in control of the overall spectrum of the integrated quantum cascade laser source. Other embodiments are described and claimed.

### PRIORITY CLAIM

This application claims the benefit of U.S. Provisional Application No. 60/902,302, filed 20 Feb. 2007.

### GOVERNMENT INTEREST

The invention claimed herein was made in the performance of work under a NASA contract, and is subject to the provisions of Public Law 96-517 (35 USC 202) in which the Contractor has elected to retain title.

### FIELD

The present invention relates to quantum cascade lasers.

### BACKGROUND

Quantum cascade lasers are semiconductor devices that emit electromagnetic radiation in the mid-to far infrared frequency spectrum, with numerous applications, such as for example chemical monitoring, medical diagnostics, collision avoidance using lidar, and free space communication, to name just a few. Quantum cascade laser are unipolar devices, where a single type of carrier, usually electrons, emit photons when transitioning from an energy band to a lower energy band. Energy bands are engineered with the use of quantum wells. A quantum cascade laser comprises a number of active regions, each active region including an injector region adjacent to a quantum well. Electrons tunnel through an injector region so as to be injected into an adjacent quantum well. The energy bands are structured such that an electron injected into a quantum well emits a photon when transitioning from an energy band to a lower energy band within that quantum well, where the electron then tunnels through the next injector to the next quantum well, where it again may transition from an energy band to a lower energy band within that next quantum well to emit another photon. This cascading process continues, and is one of the reasons why quantum cascade lasers are efficient sources of laser radiation.

For some applications, it is desirable to have a tunable broadband laser source. For example, a tunable broadband source may be of utility in probing gases for their chemical makeup, where the spectral content of the probing signal gives information about the chemical species, or may be of utility in a communication system, to name a couple of examples.

FIG. 1 illustrates in a simplified pictorial cross-sectional view a prior art quantum cascade laser for providing broadband radiation. In between cladding layers 102 and 104 are two active regions, each providing radiation at a different wavelength. For ease of illustration, only two active regions are illustrated in FIG. 1, active region 106 to provide radiation having a first wavelength (λ₁) and active region 108 to provide radiation having a second wavelength (λ₂). In practice, however, there may many active regions, each one providing electromagnetic radiation at a different wavelength. The index of refraction of cladding layers 102 and 104 are less than that of the active regions, so that the structure of layers 102, 104, 106, and 108 form a ridge waveguide. In the particular example of FIG. 1, a voltage potential is provided between metal layer 110 and substrate layer 112, and the electromagnetic propagation is along the z-axis direction as indicated by the XYZ coordinate system illustrated in FIG. 1.

Each active region in FIG. 1 includes an injector region with an adjacent quantum well. A quantum well may be referred to as gain region. The injector region usually is a superlattice. The layers making up the superlattice injector regions and the quantum wells are formed along the y-axis direction by various well-known techniques, such as molecular beam epitaxy. By including many active regions, each emitting electromagnetic radiation at a different wavelength, a broadband laser source may be synthesized. However, a problem with quantum cascade lasers of the type depicted in FIG. 1 is that it may be difficult to control the individual active regions. For example, some active regions may provide more power than other active regions, and it may be difficult to individually tune the active regions so as to provide a desired spectral laser output.

### BRIEF DESCRIPTION OF THE DRAWINGS

FIG. 1 illustrates a cross sectional view of a prior art multi-band quantum cascade laser.

FIGS. 2 and 3 illustrate cross-sectional views of a quantum cascade laser according to an embodiment.

FIG. 4 illustrates a perspective view of a quantum cascade laser according to an embodiment.

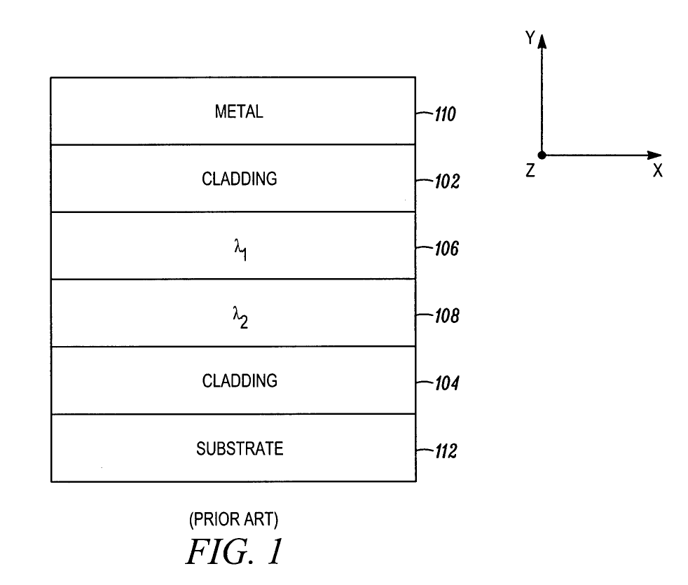

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

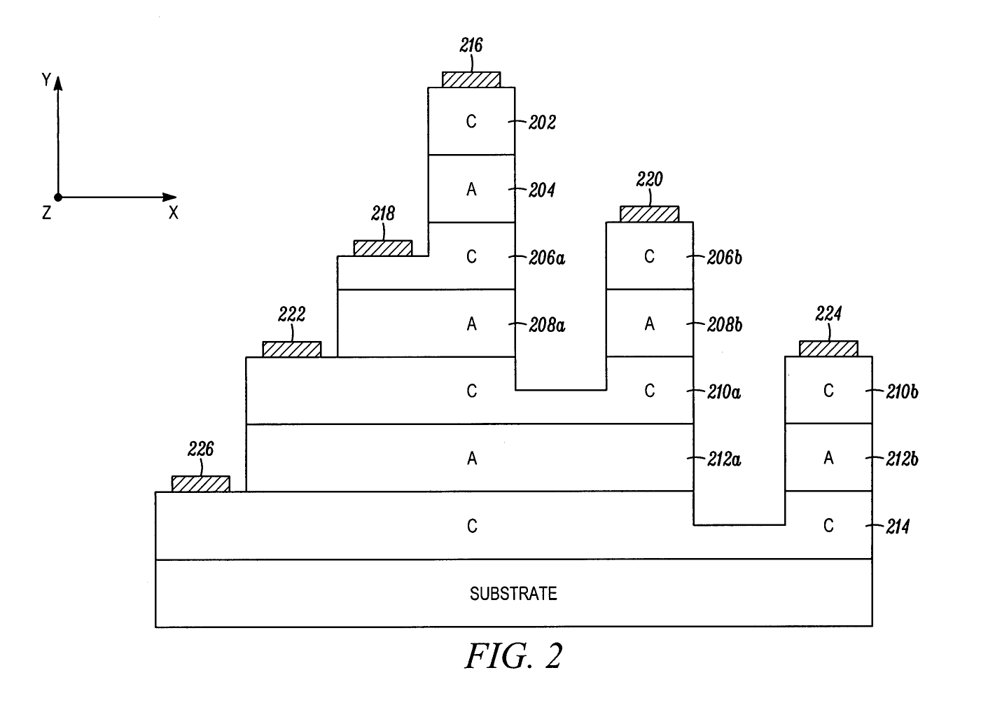

FIG. 2 illustrates is a simplified pictorial cross-sectional representation of a quantum cascade laser according to an embodiment, where for ease of illustration, only three ridge waveguide lasers are shown. In practice, there may be many individual ridge waveguide lasers, each emitting electromagnetic radiation at a different wavelength so as to provide a broadband source of radiation. A layer with a letter “c” denotes a cladding layer, and a layer with the letter “a” denotes an active layer, where an active layer includes an injector region and an adjacent quantum well (gain region).

Layers 202, 204, and 206a comprise a first quantum cascade laser, layers 206b, 208b, and 210a comprise a second quantum cascade laser, and layers 210b, 212b, and 214 comprise a third quantum cascade laser. Current is injected into the first quantum cascade laser by applying a voltage difference to metal contact layers 216 and 218. Similarly, a voltage difference applied to metal contact layers 220 and 222 provides current to the second quantum cascade laser, and a voltage difference applied to metal contact layers 224 and 226 provides current to the third quantum cascade laser. These three voltage differences may be applied independently of each other. This allows individual control of each quantum cascade laser.

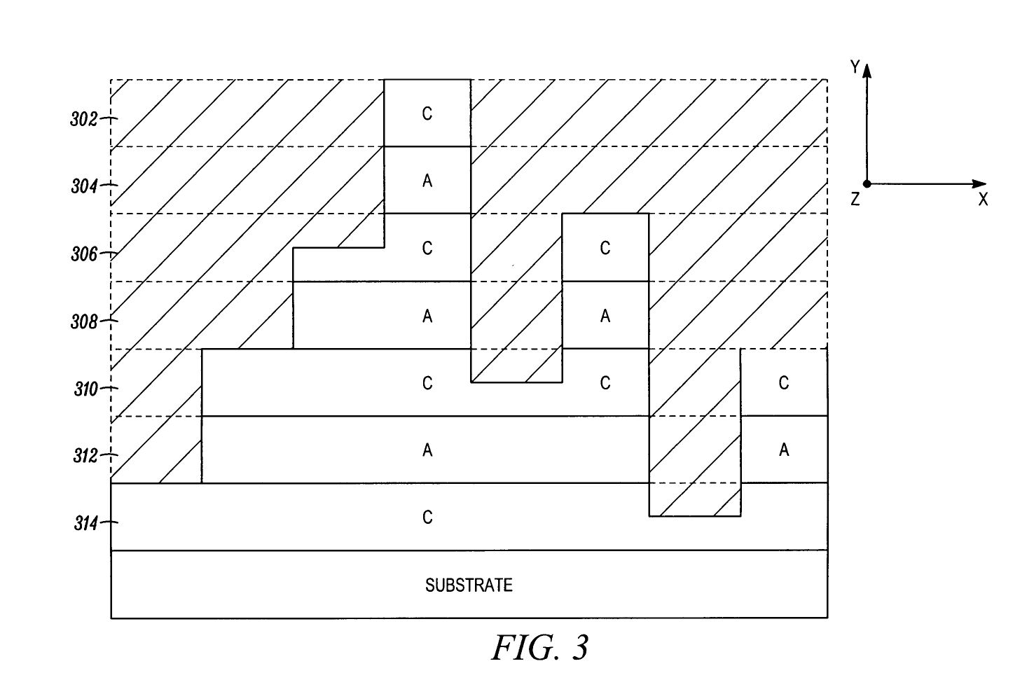

The three quantum cascade lasers shown in FIG. 2 are formed from a single monolithic structure comprising various layers of cladding and active regions. This is made clear by referring to FIG. 3, where the crosshatched region denotes that portion of the monolithic structure which has been etched away. Note that in FIG. 3 the metal contact layers are not shown. In FIG. 3, layers 302 through 314 are alternating layers of cladding and active regions. The correspondence between the layers in FIG. 3 and the layers in FIG. 2 is easily made. Cladding layer 202 in FIG. 2 is that part of cladding layer 302 remaining after an etching process. Active region layer 204 in FIG. 2 is that part of active region layer 304 in FIG. 3 remaining after the etching process. Cladding layers 206a and 206b in FIG. 2 are those parts of cladding layer 306 remaining after the etching process.

Continuing with making the correspondence between FIG. 2 in FIG. 3, active region layers 208a and 208b are formed from the active region layer 308, cladding layers 210a and 210b are formed from cladding layer 310, active region layers 212a and 212b are formed from active region layer 312, and cladding layer 214 is formed from cladding layer 314. Metal contact layers 216, 218, 220, 222, 224, and 226 are formed by depositing metal on their respective layers. Standard semiconductor processing techniques may be used to form the structure indicated in FIG. 2 from the monolithic structure indicated in FIG. 3.

It is a matter of semantics whether one may consider layers 206a and 206b to be two distinct layers or one layer, for they are formed from the same layer (306) by an etching process. Similar remarks apply to some of the other layers, such as for example layers 208a and 208b which are formed from the single layer 308, and so forth. However, note that active region layer 208a does not play an active role in the quantum cascade laser formed from layers 202, 204, and 206a, nor does it play an active role in the quantum cascade laser formed from layers 206b, 208b, and 210a. Because of the etching process, layer 208a is electrically isolated from (i.e., not in electrical contact with) active layer 208b.

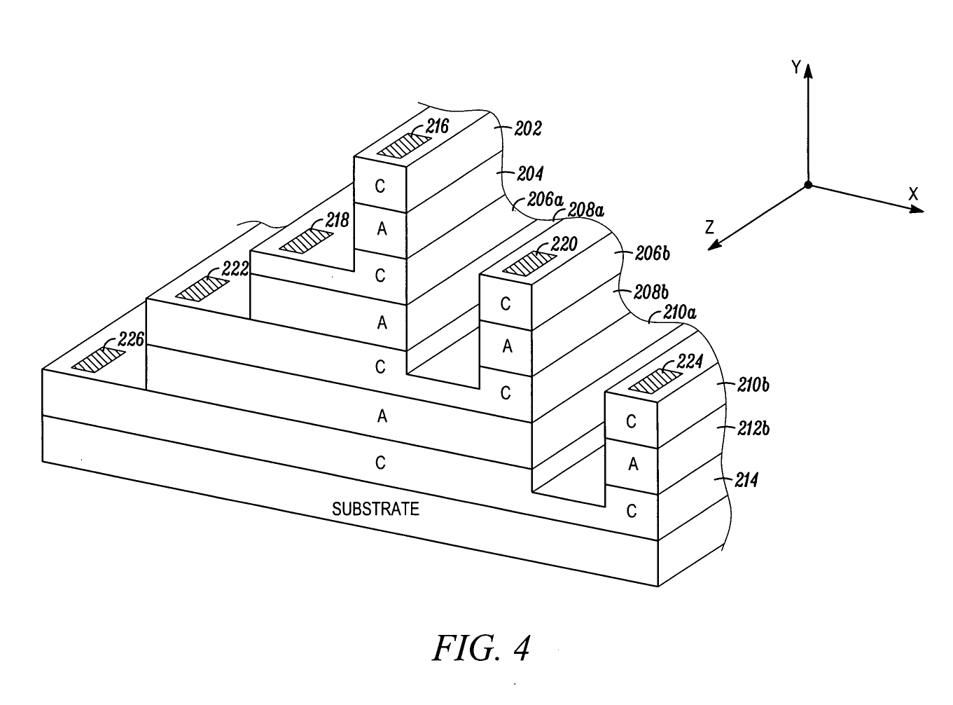

A simplified perspective view of the embodiments of FIG. 2 is illustrated in FIG. 4. The numerals in FIG. 2 indicating the various components of the embodiment are also used in FIG. 4 to denote the same components. Note the orientation of the XYZ coordinate system in FIG. 4 relative to that of the previous figures. Propagation is along the z-axis direction. For other embodiments, an etching process may be used so that the shapes of cladding layers 206a, 210a, and 214, and the layers beneath them, are such that contacts 218, 212, and 226 may be placed to the right of their respective quantum cascade lasers, where the “right” direction may be taken along the positive x-axis direction of the XYZ coordinate system.

For some embodiments, a typical cross-sectional size for a ridge waveguide quantum cascade laser is about 1.5 μm wide by about 14 μm high, where width refers to the x-axis direction and height refers to the y-axis direction. Although not shown in FIG. 4, Bragg diffraction gratings may be formed on each of the top cladding layers for each quantum cascade laser so that a single waveguide mode is amplified in each quantum cascade laser. For each quantum cascade laser, a high reflective coating may be formed on a face, where the other face serves as a partial reflector, so that an optical cavity, such as for example a Fabre Perot cavity, may be realized. (The faces are parallel to the x-y plane.) For some embodiments the cavity length for each quantum cascade laser may be on the order of 1.5 mm to 3 mm. For some embodiments the separation between each quantum cascade laser may be about 50 μm. The height of the overall structure depends upon how many quantum cascade lasers are formed, but a typical height for some embodiments may be about 100 μm.

The ridge waveguide quantum cascade lasers and metal contact pads may be defined by a combination of photo-lithographic patterning, dry and wet etching, oxide and metal evaporation, and MOCVD (metal-organic chemical vapor deposition) epitaxial growth. Various materials may be used for the cladding layers, the injectors and quantum wells within the active region layers, and the substrate. The materials for the cladding layers and active region layers may be lattice strained or lattice matched to their respective substrates.

For some embodiments, the compounds InP, GaAs, or GaSb may be used for a substrate. Superlattice structures may be used in the cladding layers and active region layers. Particular examples include a GaInAs/AlInAs (gallium indium arsenide/aluminum indium arsenide) heterostructure on an InP substrate; an AlGaAs/GaAs (aluminum gallium arsenide/gallium arsenide) heterostructure on a GaAs substrate; and an AlGaSb/InAs (aluminum gallium antimonide/indium arsenide) heterostructure on a GaSb substrate. Further examples include a superlattice composition of GaInAs/AlInAs for a quantum cascade laser on an InP substrate; a superlattice composition of AlSb/InAs for a quantum cascade laser on a GaSb substrate; and a superlattice composition of AlGaAs/GaAs for a quantum cascade laser on a GaAs substrate. Of course, these are just particular examples for the materials which may be used in an embodiment. Other materials may be used in other embodiments. Typical wavelengths for the laser radiation may be in the range of 5 μm to 20 μm.

As discussed earlier, each of the quantum cascade lasers making up an embodiment may be individually controlled by way of the applied voltage potentials. Because of this, it is expected that embodiments may find numerous applications in which a mid-to far infrared broadband laser source is desired. For example, an embodiment may be used in a frequency division multiple access communication system, where each of the individual ridge waveguide quantum cascade lasers are turned on and off in some specified fashion.

What is claimed is:

1. An apparatus comprising:
a first quantum cascade laser;
a second quantum cascade laser comprising a cladding layer; and
an active region layer adjacent to and in contact with the first quantum cascade laser and the cladding layer.

2. The apparatus is set forth in claim 1, further comprising:
a third quantum cascade laser comprising a cladding layer; and
a second active region layer adjacent to and in contact with the cladding layer of the second quantum cascade laser and the cladding layer of the third quantum cascade laser.

3. The apparatus as set forth in claim 2, the first quantum cascade laser having a quantum well with a first energy bandgap, the second quantum cascade laser having a quantum well with a second energy bandgap, and the third quantum cascade laser having a quantum well with a third energy bandgap, where the first, second, and third energy bandgaps are different from each other.

4. The apparatus as set forth in claim 2, the first quantum cascade laser tuned to provide electromagnetic radiation having a first wavelength, the second quantum cascade laser tuned to provide electromagnetic radiation having a second wavelength, and the third quantum cascade laser tuned to provide electromagnetic radiation having a third wavelength, where the first, second, and third wavelengths are different from each other.

5. An apparatus comprising:
a first cladding layer;
a first active region layer formed on the first cladding layer and comprising a quantum well and an injector to inject electrons into the quantum well, the first active region layer etched into a first part and a second part not in contact the first part;
a second cladding layer formed on the first active region layer, the second cladding layer etched into a first part and a second part not in contact with the first part of the second cladding layer, wherein the first part of second cladding layer is in contact with the first part of the first active region layer, and the second part of the second cladding layer is in contact with the second part of the first active region layer;
a second active region layer formed on the second cladding layer and comprising a quantum well and an injector to inject electrons into the quantum well of the second active region layer, the second active region layer etched to not contact the second part of the second cladding layer; and
a third cladding layer in contact with the second active region layer.

6. The apparatus as set forth in claim 5, further comprising:
a first metal contact formed on the first cladding layer;
a second metal contact formed on the first part of the second cladding layer;
a third metal contact formed on the second part of the second cladding layer; and
a fourth metal contact formed on the third cladding layer.

7. The apparatus as set forth in claim 6, the first, second, and third cladding layers having indices of refraction, and the first and second active region layers having indices of refraction, wherein the index of refraction of the first active region layer is greater than the indices of refraction of the first and second cladding layers, and the index of refraction of the second active region layer is greater than the indices of refraction of the second and third cladding layers.

8. The apparatus as set forth in claim 5, the first, second, and third cladding layers having indices of refraction, and the first and second active region layers having indices of refraction, wherein the index of refraction of the first active region layer is greater than the indices of refraction of the first and second cladding layers, and the index of refraction of the second active region layer is greater than the indices of refraction of the second and third cladding layers.

9. The apparatus as set forth in claim 5, the quantum well of the first active region layer having a first energy bandgap, and the quantum well of the second active region layer having a second energy bandgap different than the first energy bandgap.

10. An apparatus comprising:
a first cladding layer;
a first active region layer adjacent to the first cladding layer and comprising an injector and a quantum well;
a second cladding layer comprising a first part and a second part not in electrical contact with the first part, the first part adjacent to the first active region layer;
a second active region layer comprising a first part and a second part not in electrical contact with the first part of the second active region layer, the second part of the second active region layer adjacent to the second part of the second cladding layer and comprising an injector and a quantum well; and
a third cladding layer adjacent to the first and second parts of the second active region layer.

11. The apparatus as set forth in claim 10, the first, second, and third cladding layers having indices of refraction, and the first and second active region layers having indices of refraction, wherein the index of refraction of the first active region layer is greater than the indices of refraction of the first and second cladding layers, and the index of refraction of the second active region layer greater than the indices of refraction of the second and third cladding layers.

12. The apparatus as set forth in claim 11, the quantum well of the first active region layer having a first energy bandgap, and the quantum well of the second active region layer having a second energy bandgap different from the first energy bandgap.

13. The apparatus as set forth in claim 10, the quantum well of the first active region layer having a first energy bandgap, and the quantum well of the second active region layer having a second energy bandgap different from the first energy bandgap.

14. The apparatus as set forth in claim 10, further comprising:
a first metal contact formed on the first cladding layer;
a second metal contact formed on the first part of the second cladding layer;
a third metal contact formed on the second part of the second cladding layer; and
a fourth metal contact formed on the third cladding layer.

15. The apparatus as set forth in claim 14, the first, second, and third cladding layers having indices of refraction, and the first and second active region layers having indices of refraction, wherein the index of refraction of the first active region layer is greater than the indices of refraction of the first and second cladding layers, and the index of refraction of the second active region layer greater than the indices of refraction of the second and third cladding layers.

16. The apparatus as set forth in claim 15, the quantum well of the first active region layer having a first energy bandgap, and the quantum well of the second active region layer having a second energy bandgap different from the first energy bandgap.
